(19) United States
(12) Patent Application Publication
(10) Pub. No.: US 2026/0004863 A1
(43) Pub. Date: Jan. 1, 2026

(54) ADAPTIVE PROGRAM VERIFY SCHEME WITH SENSISTIVE VERIFY FOR DEFECT DETECTION

(71) Applicant: Micron Technology, Inc., Boise, ID (US)

(72) Inventors: Yu-Chung Lien, San Jose, CA (US); Zhenming Zhou, San Jose, CA (US)

(21) Appl. No.: 19/232,087

(22) Filed: Jun. 9, 2025

Related U.S. Application Data
(60) Provisional application No. 63/665,906, filed on Jun. 28, 2024.

(51) Int. Cl. G11C 29/08

(52) U.S. Cl. CPC G11C 29/08

(57) ABSTRACT

A system includes a memory device and a processing device, operatively coupled with the memory device, to perform operations including receiving a command to perform a program operation on a block of the memory device; determining whether the block is on an exclusion list; determining, in response to determining that the block is not on the exclusion list, whether a value of a media endurance metric of the block satisfies a media endurance metric criterion; performing, in response to determining that the value of the media endurance metric of the block satisfies the media endurance metric criterion, the program operation on the block; determining whether a media health metric of the block satisfies a health threshold criterion; and adding, in response to determining that the media health metric of the block satisfies the health threshold criterion, the block to the exclusion list.

### REFERENCE TO RELATED APPLICATION

This application claims the priority benefit of U.S. Provisional Patent Application No. 63/665,906, filed June 28, 2024, the entirety of which is incorporated herein by reference.

### TECHNICAL FIELD

Embodiments of the disclosure relate generally to memory sub-systems, and more specifically, relate to implementing an adaptive program verify scheme with sensitive verify to detect defects in a memory device in a memory sub-system.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1A illustrates an example computing system that includes a memory sub-system, in accordance with one or more embodiments of the present disclosure.

FIG. 1B is a block diagram of memory device(s) in communication with a memory sub-system controller of a memory sub-system, in accordance with one or more embodiments of the present disclosure.

FIG. 2 is a schematic of portions of an array of memory cells, according to some embodiments.

FIG. 3 is a flow diagram of an example method implementing an adaptive program verify scheme with sensitive verify in a memory sub-system, in accordance with one or more embodiments of the present disclosure.

FIG. 4 illustrates example adaptive program verify scheme with sensitive verify, in accordance with one or more embodiments of the present disclosure.

FIG. 5 is a flow diagram of an example method implementing an adaptive program verify scheme with sensitive verify in a memory sub-system, in accordance with one or more embodiments of the present disclosure.

FIG. 6 is a block diagram of an example computer system in which embodiments of the present disclosure may operate.

### DETAILED DESCRIPTION

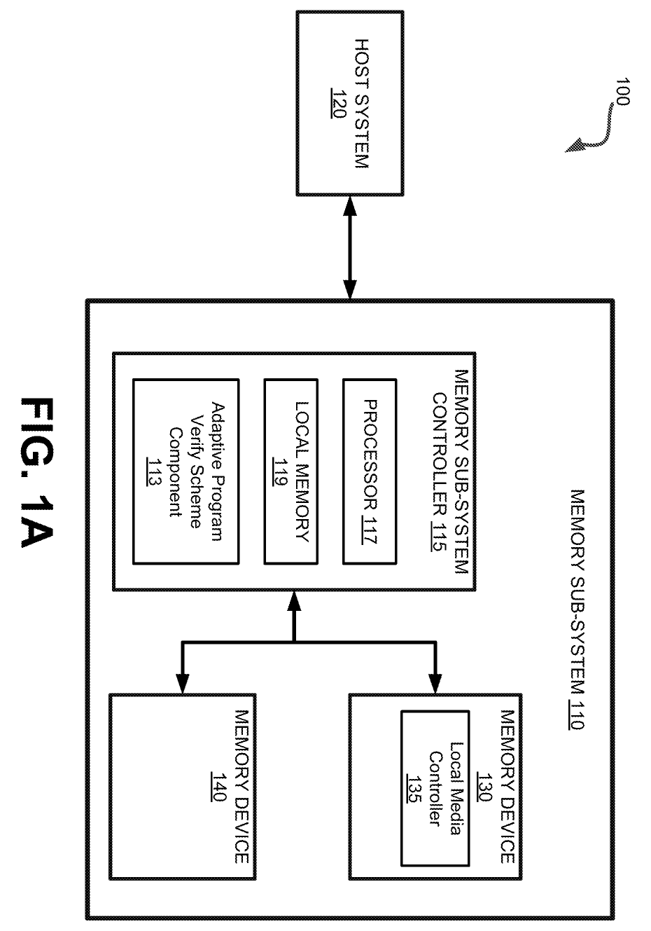

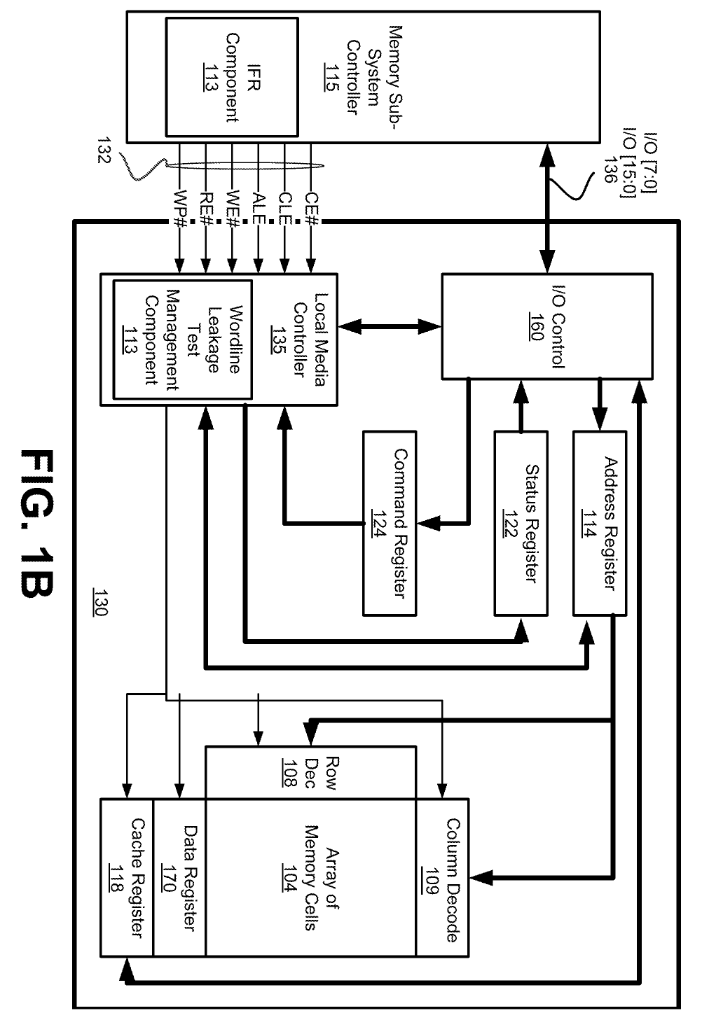

Aspects of the present disclosure are directed to implementing an adaptive program verify scheme with a sensitive verify operation (e.g., an in-field read operation) for detecting defects and avoiding uncorrectable error correction code (UECC) errors in one or more blocks and/or sub-blocks of a memory device in a memory sub-system. A memory sub-system can be a storage device, a memory module, or a hybrid of a storage device and memory module. Examples of storage devices and memory modules are described below in conjunction with FIG. 1A. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. For example, not AND (NAND) memory, such as 3D flash NAND memory, offers storage in the form of compact, high density configurations. A non-volatile memory device is a package of one or more dice, each including one or more planes. For some types of non-volatile memory devices (e.g., NAND memory), each plane includes of a set of physical blocks. Each block includes of a set of pages. Each page includes of a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

A memory device can include multiple memory cells arranged in a two-dimensional or a three-dimensional grid. The memory cells are formed onto a silicon wafer in an array of columns and rows. The memory cells are joined by wordlines, which are conducting lines electrically connected to the control gates of the memory cells, and bitlines, which are conducting lines electrically connected to the drain electrodes of the memory cells. The intersection of a bitline and wordline constitutes the address of the memory cell. A block hereinafter refers to a unit of the memory device used to store data and can include a group of memory cells, a wordline group, a wordline, or individual memory cells. One or more blocks can be grouped together to form separate partitions (e.g., planes) of the memory device in order to allow concurrent operations to take place on each plane. The memory device can include circuitry that performs concurrent memory page accesses of two or more memory planes. For example, the memory device can include a respective access line driver circuit and power circuit for each plane of the memory device to facilitate concurrent access of pages of two or more memory planes, including different page types.

One example of a memory sub-system is a solid-state drive (SSD) that includes one or more non-volatile memory devices and a memory sub-system controller to manage the non-volatile memory devices. A given segment of one of those memory devices (e.g., a block) can be characterized based on the programming state of the memory cells associated with wordlines contained within the segment. In some cases, during each program operation to a different wordline, a program pulse is generated to program the wordline followed by a separate program verify operation to verify the threshold voltages of the programmed cells of that wordline. This program verify scheme is referred to herein as a one-program one-verify (1P1V) scheme.

The purpose of the program verify operation is to check whether the sub-block has been programmed to a particular threshold program verify voltage and determine whether the programming has completed. In some cases, the program verify operation is skipped such that a program pulse is applied with no subsequent verification during the program operation. This program verify scheme is referred to herein as a one-program zero-verify (1P0V) scheme. A 1P0V scheme has demonstrated several advantages over a 1P1V scheme, such as reduced program operation time, better sequential writing performance, and reduced energy consumption of program operations.

As described above, a non-volatile memory device can include a number of individual blocks, each having a set of one or more wordlines that are used to access the memory cells of the block. Over time, as memory access operations, including program operations, read operations, and erase operations, are repeatedly performed on the blocks of the memory device, certain defects can develop. Defects can occur in memory devices due to the manufacturing process and can occur during the operating life of the memory device. For example, an electrical short can develop between two adjacent wordlines. When a certain voltage, such as a program voltage, is applied to one of those wordlines, a current is developed, at least a portion of which can flow through the electrical short and onto the adjacent wordline. This portion of the current can be referred to as a “leakage current” or “wordline leakage”. Wordline leakage can impact the logical values programed to or read from the memory cells connected to the associated wordlines leading to errors on the memory device.

In some cases, the memory sub-system can employ an error detection/correction method (e.g., by using an error correction code (ECC)) capable of detecting the defect and correcting a certain number of errors, for example, at the time of the read operation. When the detection/correction method is not capable of correcting the errors within the data being read, an ECC failure can occur and can be referred to as an uncorrectable ECC error (UECC error). Certain physical defects, including a wordline to wordline short, are considered as UECC errors and, responsive to detecting such an error, the memory sub-system can retire the corresponding block such that it is not used to store data going forward. However, retiring the corresponding block cannot compensate for loss of the data that has already occurred. That is, the wordline leakage-related defects (e.g., current leakage from one wordline to another or to the substrate) causes the faulty wordline to fail to program and corresponding data is corrupted, resulting in data loss and a reduction in reliability.

Use of the 1P0V scheme—despite its benefits—can lead to uncorrectable error correction code (UECC) errors during the read stage due to undetected program status failures (PSFs) at the program phase. PSFs can result from defects per million (DPM), which are defects in the array that can occur during manufacturing and can develop over repeated program/erase cycles (PECs) into grown bad blocks (GBBs). The redundant array of independent NAND (RAIN) technique helps manage UECC errors by providing additional redundancy and error correction. It distributes data across multiple NAND flash chips with parity information, allowing data recovery even if ECCs fail. This enhances reliability and ensures data can be reconstructed despite uncorrectable errors. However, reducing the amount of RAIN SRAM in a memory device can improve overall system performance, particularly in mNAND zoned namespace (ZNS) products, limiting its ability to recover data after a UECC error.

Detecting PSFs at the program phase is crucial because early detection allows data recovery without relying on RAIN SRAM. For example, if a PSF is detected early (e.g., at the program stage), the data can be recovered without relying on RAIN SRAM because the system buffer retains the host data until program verify operation is complete. However, if a PSF is missed during the program stage and the system buffer is cleared prematurely, it can lead to a UECC read error. As devices trend towards reduced amounts of RAIN SRAM in order to enhance performance, the decreased capacity to manage data recovery makes UECC errors more critical.

In order to reduce program operation time, improve sequential writing performance, and reduce energy consumption, in devices with a 1-wordline RAIN protection scheme the 1P1V scheme can be performed on only one sub-block of each wordline. In devices with a 2-wordline RAIN protection scheme, the 1P1V scheme is performed on only one sub-block of every other wordline (e.g., alternating wordlines). Each sub-block of a wordline shares the same print (trace), allowing wordline leakage in any sub-block to be detected by program verification in another sub-block sharing the same wordline. Using the 1P1V scheme on many sub-blocks (e.g., on one sub-block of each wordline or every other wordline) reduces the risk of missing a PSF and prevents more UECC errors but increases the effective programming time, negatively affecting sequential write performance and energy consumption.

To achieve target performance the 1P1V scheme is performed on as few sub-blocks as possible, favoring the 1P0V scheme, as fewer verifies lead to faster programming time. However, this tradeoff increases the risk of missing a PSF during the program stage, which can lead to critical UECC errors during the read phase.

Aspects of the present disclosure address the above and other issues by implementing an adaptive program verify scheme employing a sensitive verify (e.g., an in-field read (IFR) operation that can detect very low leakage currents) for detecting PSFs during the program stage and avoiding UECC errors in a memory device. For example, a system includes a memory device coupled to a processing device that performs operations to implement the adaptive program verify scheme employing a sensitive verify operation (e.g., an in-field read operation) dependent on PEC count, ensuring efficient use of the memory device while maintaining its health and endurance. A sensitive verify operation, such as an in-field read operation, can be detect small leakage currents that standard verify operations may not detect. The enhanced sensitivity ensures the detection and of subtle defects.

In some embodiments, the in-field read operation is performed during the lifecycle of a memory device (referred to as "in-field") with the primary objective of identifying and detecting blocks that have defects. These defects could include issues such as wordline leakage. By performing this in-field read operation and detecting defects, it becomes possible to increment the corresponding failing byte (CFByte) counts for these problematic blocks. Once a block's CFByte count reaches or exceeds a predetermined health criterion threshold, it is then placed on an exclusion list to ensure that it does not compromise data integrity and performance of the memory subsystem. In some embodiments, the blocks on the exclusion list would not be programed using the 1P0V scheme because the high potential risk a PSF would not allow omitting the verify operation. Conversely, the in-field read operation may take place after a program operation that does not involve a standard program verify phase. The primary objective of the in-field read operation is to identify and detect blocks with defects (such as wordline leakage) within the memory device. Wordline leakage in NAND flash memory refers to unintended electrical current that flows between adjacent wordlines or from a wordline to the substrate, potentially causing data errors. This leakage can lead to corrupted data in the memory cells connected to the affected wordline, impacting the overall reliability of the memory block. By performing this in-field read operation, it becomes possible to increment the corresponding count failure byte (CFByte) counts for these problematic blocks. Once a block's CFByte count reaches or exceeds the health criterion threshold, it is then placed on an exclusion list to ensure that it does not compromise data integrity and performance of the memory subsystem.

The in-field read operation is more sensitive, compared to a standard verify operation, in defect detection because the selected wordline in the in-field read operation is disconnected from the voltage supply and left floating for a time period (“voltage floating phase”), which can result in an amplified charge difference for detecting defects such as leakages. Also, because the outcome of the in-field read operation is defect detection, not data retrieving, the in-field read operation can be performed in parallel to multiple sub-blocks. By using a sensitive verify operation, such as an in-field read operation, the processing device can detect a wordline leakage of less than one nano amp.

In some embodiments, the processing device receives a command to perform a program operation (e.g., a command to write data such as a dynamic SLC program command) on a block within the memory device. Before performing the operation, the processing device determines if the block is found on an exclusion list. This could be a block that has been marked for special treatment (e.g., a different program erase scheme is used on the block than on other blocks not on the exclusion list) due to, for example, detected wordline leakage and/or a high CFByte count.

In some embodiments, the leakage current (e.g., wordline leakage) in a memory device can cause unintended changes in stored data, leading to errors (e.g., PSFs). These errors can be detected by error correction mechanisms of the memory device during read operations. Specifically, the error-correcting code (ECC) identifies and corrects errors resulting from leakage currents. The CFByte count is utilized to track the frequency of these detected errors. For example, a high CFByte value indicates frequent errors due to issues like wordline leakage. Each time an error is identified and corrected (e.g., using an in-field read operation), the CFByte count is incremented, providing a metric (e.g., a media health metric) for monitoring the health and reliability of a block. When the CFByte count exceeds a predefined threshold, it may trigger actions such as marking the block as bad (e.g., exclusion list), relocating data, etc.

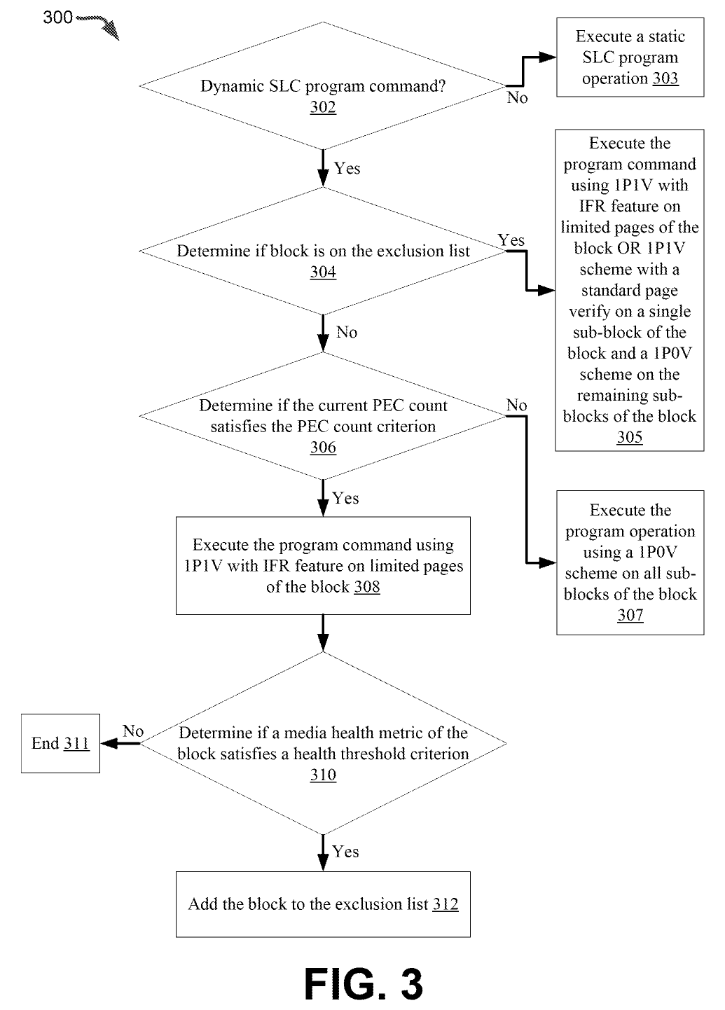

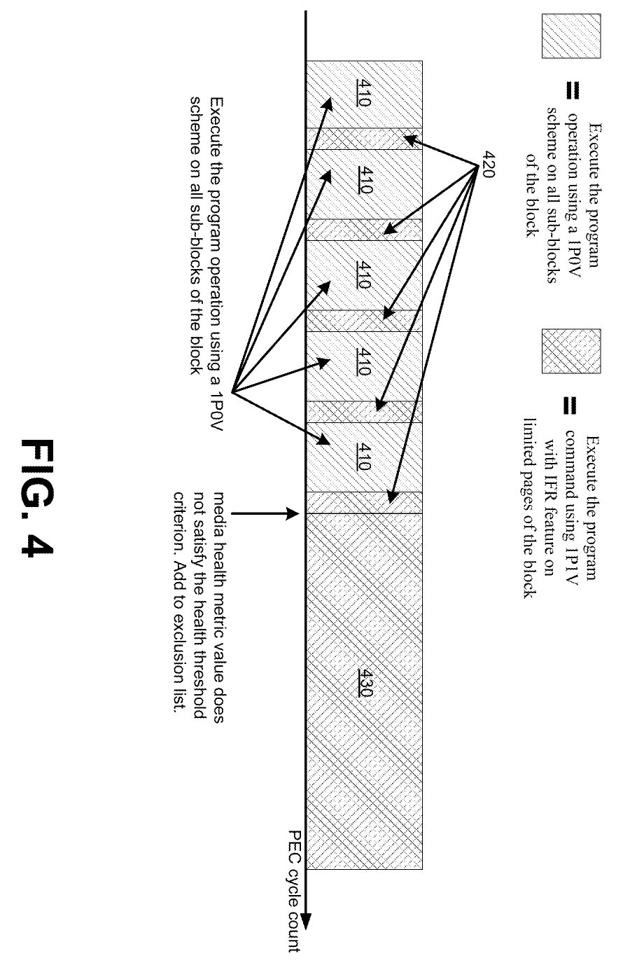

In some embodiments, if the processing device determines that the block is on the exclusion list, the processing device performs the program operation using a 1P1V scheme with a sensitive verify operation (an in-field read operation that can detect very low leakage currents, which is further described in FIGS. 3-4) on only a subset of the pages of the block (e.g., the pages corresponding to a single sub-block). In some embodiments, wordlines with a reliability risk can be identified (e.g., by performing a statistical study). For example, the program operation using the 1P1V scheme with the sensitive verify operation can be performed on a subset of the pages of the block corresponding to the wordlines with a reliability risk. In some embodiments, the 1P1V scheme with the sensitive verify operation can be performed on the pages corresponding to an arbitrarily chosen sub-block. In some embodiments, the 1P1V scheme with a sensitive page verify need not be performed on each sub-block of a block because the sub-blocks of a block can share wordlines. Therefore, verifying that a single sub-block has little or no wordline leakage can indicate that the remaining sub-blocks in the block also have little or no wordline leakage. Alternatively, the processing device may perform the 1P1V scheme with a standard verify operation on a single sub-block of the block and a 1P0V scheme is performed on the remaining sub-blocks of the block.

If the block is not on the exclusion list, the processing device then checks whether a media endurance metric value (e.g., a program erase cycle (PEC) count) of the block meets a media endurance metric criterion. For example, the media endurance metric criterion can be satisfied when media endurance metric value of a block is equal to one or more media endurance metric criterion values. In some embodiments, these media endurance metric criterion values can be periodic (e.g., occurring at regular, fixed intervals, such as every 1,000 program/erase cycles, 10,000 program/erase cycles, 50,000 program/erase cycles, etc.). In some embodiments, these media endurance metric criterion values can be random (e.g., occurring at irregular or unpredictable intervals). For example, a media endurance metric value of a block can be the PEC count of the block. The PEC count of the block may satisfy the media endurance metric criterion at 10,000 PECs, 20,000 PECs, 30,000 PECs, etc. The media endurance metric criterion can serve as a checkpoint during the life of a block, allowing the processing device to periodically (or randomly) assess the block for any developing defects (e.g., such as wordline leakage) by using a sensitive read operation (e.g., an in-field read operation).

If the media endurance metric value of the block satisfies the media endurance metric criterion, the processing device proceeds with the program operation on that block using a 1P1V scheme that incorporates a sensitive verify (e.g., an in-field read (IFR) verify). This program operation on the block using the 1P1V scheme that incorporates a sensitive verify serves as a checkpoint for the block to determine whether the block should be added to the exclusion list. In some embodiments, the page program and the sensitive page verify are performed on only a subset of the pages of the block. In some embodiments, wordlines with a potential reliability risk can be identified through methods such as statistical analysis. For example, a program operation utilizing a 1P1V scheme with a sensitive verify operation can be selectively applied to a subset of pages within a block that correspond to these identified wordlines. Since the sub-blocks within a block share wordlines, verifying that a single sub-block has little or no wordline leakage can indicate that the remaining sub-blocks in the block also have little or no wordline leakage.

The processing device can then determine if a media health metric value (e.g., a CFByte count, a wordline leakage current value, etc.) of the block satisfies a health threshold criterion. In some embodiments, the health threshold criterion is satisfied when a CFByte count of a block is greater than or equal to a CFByte threshold value. If the processing device determines that the media health metric value of the block satisfies the health threshold criterion the processing device adds the block to the exclusion list. In some embodiments, the health threshold criterion is satisfied when a wordline leakage current of the block is greater than or equal to a wordline leakage current threshold value. In some embodiments, the wordline leakage current threshold value can be determined by comparing the leakage current values observed in typical operational scenarios (e.g., little to no leakage current) with those in scenarios where wordline leakage is present. The threshold value can be set based on the current values from normal operational scenarios, incorporating a margin to avoid falsely flagging non-leakage conditions as leakage. The determination of the wordline leakage current threshold value involves a trade-off in setting the threshold value to balance accuracy (correctly identifying true leakage conditions) and reliability (minimizing false positives and ensuring stable operation).

If the media endurance metric value does not meet the media endurance metric criterion (e.g., the PEC count of the block does equal at least one of the PEC count values that satisfy the media endurance metric criterion), the processing device performs the program operation without any subsequent page verifications (1P0V) to reduce program operation time, improve sequential writing performance, and reduce energy consumption for the blocks that are not on the detention list and do not satisfy the media endurance metric criterion.

Advantages of the present disclosure include the ability to detect PSFs during the program stage (e.g., using the in-field read feature), allowing for data recovery without relying on RAIN SRAM and significantly reducing the number of verify operations performed. Further, by reducing the number of verify operations performed programming time is improved. Advantages of the present disclosure further include reduced data loss and increased reliability. By detecting PSFs in blocks at the program stage the blocks can be retired and UECC errors in the blocks are avoided. Advantages of the present disclosure further include the potential to reduce RAIN SRAM to improve overall performance by limiting UECC errors that necessitate RAIN SRAM for data recovery. Advantages of the present disclosure further include reduced program operation time, improved sequential writing performance, and reduced energy consumption while reducing the risk of undetected PSFs and preventing more UECC errors.

FIG. 1A illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., one or more memory device(s) 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1A illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access the memory components (e.g., the one or more memory device(s) 130) when the memory sub-system 110 is coupled with the host system 120 by the physical host interface (e.g., PCIe or CXL bus). The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device(s) 130) include negative-and (NAND) type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory device(s) 130 can include one or more arrays of memory cells. One type of memory cell, for example, single level cells (SLC) can store one bit per cell. Other types of memory cells, such as multi-level cells (MLCs), triple level cells (TLCs), and quad-level cells (QLCs), can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, or a QLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, electrically erasable programmable read-only memory (EEPROM).

A memory sub-system controller 115 (or controller 115 for simplicity) can communicate with the memory device(s) 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor 117 (e.g., a processing device) configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1A has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory device(s) 130. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory device(s) 130. The memory sub-system controller 115 can further include host interface circuitry to communicate with the host system 120 via the physical host interface. The host interface circuitry can convert the commands received from the host system into command instructions to access the memory device(s) 130 as well as convert responses associated with the memory device(s) 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory device(s) 130.

In some embodiments, the memory device(s) 130 include local media controllers 135 that operate in conjunction with memory sub-system controller 115 to execute operations on one or more memory cells of the memory device(s) 130. An external controller (e.g., memory sub-system controller 115) can externally manage the memory device 130 (e.g., perform media management operations on the memory device(s) 130). In some embodiments, a memory device 130 is a managed memory device, which is a raw memory device (e.g., memory array 104) having control logic (e.g., local controller 135) for media management within the same memory device package. An example of a managed memory device is a managed NAND (MNAND) device. Memory device(s) 130, for example, can each represent a single die having some control logic (e.g., local media controller 135) embodied thereon. In some embodiments, one or more components of memory sub-system 110 can be omitted.

In one embodiment, the memory sub-system 110 includes an adaptive program verify scheme component 113 that can implement an adaptive program verify scheme with a sensitive verify (e.g., an in-field read operation) for one or more block of memory array 104 of memory device 130 to detect PSFs and avoid UECC errors in the memory device. In an embodiment, one or more portions of the adaptive program verify scheme component 113 of the memory sub-system controller 115 can be included in the local media controller 135. Further details with regards to the operations of adaptive program verify scheme component 113 are described below.

FIG. 1B is a simplified block diagram of a first apparatus, in the form of a memory device 130, in communication with a second apparatus, in the form of a memory sub-system controller 115 of a memory sub-system (e.g., memory sub-system 110 of FIG. 1A), according to an embodiment. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), may be a memory controller or other external host device.

Memory device(s) 130 includes an array of memory cells 104 logically arranged in rows and columns. Memory cells of a logical row are connected to the same access line (e.g., a wordline) while memory cells of a logical column are selectively connected to the same data line (e.g., a bitline). A single access line may be associated with more than one logical row of memory cells and a single data line may be associated with more than one logical column. Memory cells of at least a portion of array of memory cells 104 are capable of being programmed to one of at least two target data states.

Row decode circuitry 108 and column decode circuitry 109 are provided to decode address signals. Address signals are received and decoded to access the array of memory cells 104. Memory device 130 also includes input/output (I/O) control circuitry 160 to manage input of commands, addresses and data to the memory device 130 as well as output of data and status information from the memory device(s) 130. An address register 114 is in communication with I/O control circuitry 160 and row decode circuitry 108 and column decode circuitry 109 to latch the address signals prior to decoding. A command register 124 is in communication with I/O control circuitry 160 and local media controller 135 to latch incoming commands.

A controller (e.g., the local media controller 135 internal to the memory device 130) controls access to the array of memory cells 104 in response to the commands and generates status information for the external memory sub-system controller 115, i.e., the local media controller 135 is configured to perform access operations (e.g., read operations, programming operations and/or erase operations) on the array of memory cells 104. The local media controller 135 is in communication with row decode circuitry 108 and column decode circuitry 109 to control the row decode circuitry 108 and column decode circuitry 109 in response to the addresses. In one embodiment, the memory sub-system controller 115 and the local media controller 135 include portions of the adaptive program verify scheme component 113 which are configured to enable communication between the memory sub-system controller 115 and the local media controller 135 to perform the steps and operations associated with the management of the wordline leakage testing of one or more of memory device(s) 130, in accordance with embodiments of the present application.

The local media controller 135 is also in communication with a cache register 118. Cache register 118 latches data, either incoming or outgoing, as directed by the local media controller 135 to temporarily store data while the array of memory cells 104 is busy writing or reading, respectively, other data. During a program operation (e.g., write operation), data may be passed from the cache register 118 to the data register 170 for transfer to the array of memory cells 104; then new data may be latched in the cache register 118 from the I/O control circuitry 160. During a read operation, data may be passed from the cache register 118 to the I/O control circuitry 160 for output to the memory sub-system controller 115; then new data may be passed from the data register 170 to the cache register 118. The cache register 118 and/or the data register 170 may form (e.g., may form a portion of) a page buffer of the memory device 130. A page buffer may further include sensing devices (not shown in FIG. 1B) to sense a data state of a memory cell of the array of memory cells 204, e.g., by sensing a state of a data line connected to that memory cell. A status register 122 may be in communication with I/O control circuitry 160 and the local memory controller 135 to latch the status information for output to the memory sub-system controller 115.

Memory device(s) 130 receives control signals at the memory sub-system controller 115 from the local media controller 135 over a control link 132. For example, the control signals can include a chip enable signal CE#, a command latch enable signal CLE, an address latch enable signal ALE, a write enable signal WE#, a read enable signal RE#, and a write protect signal WP#. Additional or alternative control signals (not shown) may be further received over control link 132 depending upon the nature of the memory device 130. In one embodiment, memory device 130 receives command signals (which represent commands), address signals (which represent addresses), and data signals (which represent data) from the memory sub-system controller 115 over a multiplexed input/output (I/O) bus 136 and outputs data to the memory sub-system controller 115 over I/O bus 136.

For example, the commands may be received over input/output (I/O) pins [7:0] of I/O bus 136 at I/O control circuitry 160 and may then be written into command register 124. The addresses may be received over input/output (I/O) pins [7:0] of I/O bus 136 at I/O control circuitry 160 and may then be written into address register 114. The data may be received over input/output (I/O) pins [7:0] for an 8-bit device or input/output (I/O) pins [15:0] for a 16-bit device at I/O control circuitry 160 and then may be written into cache register 118. The data may be subsequently written into data register 170 for programming the array of memory cells 104.

In an embodiment, cache register 118 may be omitted, and the data may be written directly into data register 170. Data may also be output over input/output (I/O) pins [7:0] for an 8-bit device or input/output (I/O) pins [15:0] for a 16-bit device. Although reference may be made to I/O pins, they may include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIGS. 1A-1B has been simplified. It should be recognized that the functionality of the various block components described with reference to FIGS. 1A-1B may not necessarily be segregated to distinct components or component portions of an integrated circuit device. For example, a single component or component portion of an integrated circuit device could be adapted to perform the functionality of more than one block component of FIGS. 1A-1B. Alternatively, one or more components or component portions of an integrated circuit device could be combined to perform the functionality of a single block component of FIGS. 1A-1B. Additionally, while specific I/O pins are described in accordance with popular conventions for receipt and output of the various signals, it is noted that other combinations or numbers of I/O pins (or other I/O node structures) may be used in the various embodiments.

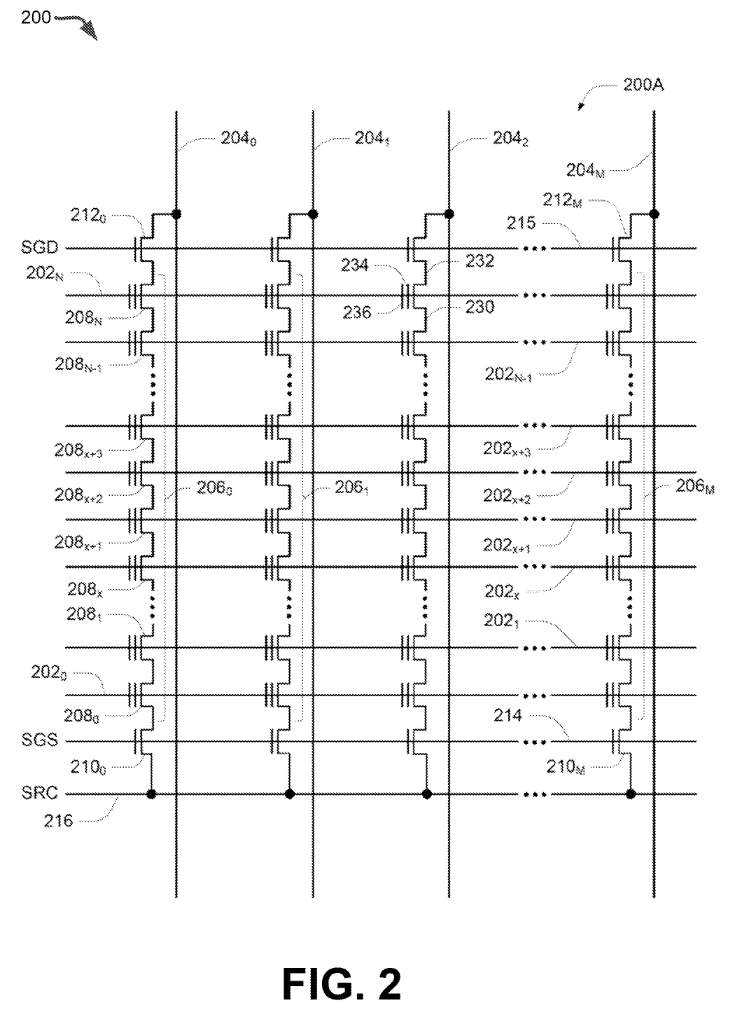

FIG. 2 is a schematic of portions of an array 200 of memory cells as could be used in a memory of the type described with reference to FIGS. 1A and 1B according to an embodiment. Memory array 200 includes access lines, such as wordlines 202₀ to 202_{N}, and data lines, such as bitlines 204₀ to 204_{M}. The wordlines 202 can be connected to global access lines (e.g., global wordlines), not shown in FIG. 2, in a many-to-one relationship. For some embodiments, memory array 200 can be formed over a semiconductor that, for example, can be conductively doped to have a conductivity type, such as a p-type conductivity, e.g., to form a p-well, or an n-type conductivity, e.g., to form an n-well.

The memory array 200 can be arranged in rows (each corresponding to a wordline 202) and columns (each corresponding to a bitline 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select gate 210 (e.g., a field-effect transistor), such as one of the select gates 210₀ to 210_{M} (e.g., that can be source select transistors, commonly referred to as select gate source), and a select gate 212 (e.g., a field-effect transistor), such as one of the select gates 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select gates 210 and 212 can utilize a structure similar to (e.g., the same as) the memory cells 208. The select gates 210 and 212 can represent a number of select gates connected in series, with each select gate in series configured to receive a same or independent control signal.

A source of each select gate 210 can be connected to common source 216, or SRC. The drain of each select gate 210 can be connected to a memory cell 208₀ of the corresponding NAND string 206. For example, the drain of select gate 210₀ can be connected to memory cell 208₀ of the corresponding NAND string 206₀. Therefore, each select gate 210 can be configured to selectively connect a corresponding NAND string 206 to the common source 216. A control gate of each select gate 210 can be connected to the select line 214.

The drain of each select gate 212 can be connected to the bitline 204 for the corresponding NAND string 206. For example, the drain of select gate 212₀ can be connected to the bitline 204₀ for the corresponding NAND string 206₀. The source of each select gate 212 can be connected to a memory cell 208_{N} of the corresponding NAND string 206. For example, the source of select gate 212₀ can be connected to memory cell 208_{N} of the corresponding NAND string 206₀. Therefore, each select gate 212 can be configured to selectively connect a corresponding NAND string 206 to the corresponding bitline 204. A control gate of each select gate 212 can be connected to select line 215.

The memory array 200 in FIG. 2 can be a quasi-two-dimensional memory array and can have a generally planar structure, e.g., where the common source 216, NAND strings 206 and bitlines 204 extend in substantially parallel planes. Alternatively, the memory array 200 in FIG. 2 can be a three-dimensional memory array, e.g., where NAND strings 206 can extend substantially perpendicular to a plane containing the common source 216 and to a plane containing the bitlines 204 that can be substantially parallel to the plane containing the common source 216.

Typical construction of memory cells 208 includes a data-storage structure 234 (e.g., a floating gate, charge trap, or the like) that can determine a data state of the memory cell (e.g., through changes in threshold voltage), and a control gate 236, as shown in FIG. 2. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. The memory cells 208 have their control gates 236 connected to (and in some cases form) a wordline 202.

A column of the memory cells 208 can be a NAND string 206 or a number of NAND strings 206 selectively connected to a given bitline 204. A row of the memory cells 208 can be memory cells 208 commonly connected to a given wordline 202. A row of memory cells 208 can, but need not, include all the memory cells 208 commonly connected to a given wordline 202. Rows of the memory cells 208 can often be divided into one or more groups of physical pages of memory cells 208, and physical pages of the memory cells 208 often include every other memory cell 208 commonly connected to a given wordline 202. For example, the memory cells 208 commonly connected to wordline 202_{N} and selectively connected to even bitlines 204 (e.g., bitlines 204₀, 204₂, 204₄, etc.) can be one physical page of the memory cells 208 (e.g., even memory cells) while memory cells 208 commonly connected to wordline 202_{N} and selectively connected to odd bitlines 204 (e.g., bitlines 204₁, 204₃, 204₅, etc.) can be another physical page of the memory cells 208 (e.g., odd memory cells).

Although bitlines 204₃-204₅ are not explicitly depicted in FIG. 2, it is apparent from the figure that the bitlines 204 of the array of memory cells 200 can be numbered consecutively from bitline 204₀ to bitline 204_{M}. Other groupings of the memory cells 208 commonly connected to a given wordline 202 can also define a physical page of memory cells 208. For certain memory devices, all memory cells commonly connected to a given wordline can be deemed a physical page of memory cells. The portion of a physical page of memory cells (which, in some embodiments, could still be the entire row) that is read during a single read operation or programmed during a single program operation (e.g., an upper or lower page of memory cells) can be deemed a logical page of memory cells. A block of memory cells can include those memory cells that are configured to be erased together, such as all memory cells connected to wordlines 202₀-202_{N} (e.g., all NAND strings 206 sharing common wordlines 202). Unless expressly distinguished, a reference to a page of memory cells herein refers to the memory cells of a logical page of memory cells. Although the example of FIG. 2 is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

FIG. 3 is a flow diagram of an example method implementing an adaptive program verify scheme with sensitive verify in a memory sub-system, in accordance with one or more embodiments of the present disclosure. The method 300 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 300 is performed by adaptive program verify scheme component 113 of FIGS. 1A and 1B. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 302, the processing logic may receive a command to perform a program operation on a block within the memory device and determine whether the command to perform a program operation is a dynamic SLC program command.

At operation 303, in response to determining that the command to perform a program operation is not a dynamic SLC program command, the processing logic can execute the program operation (e.g., a static SLC program operation).

Alternatively, at operation 304, in response to determining that the command to perform a program operation is a dynamic SLC program command the processing logic can determine if the block is included on an exclusion list (e.g., detention list). Blocks on the exclusion list can be blocks that have been marked for special treatment due to, for example, detected wordline leakage and/or a high CFByte count.

At operation 305, in response to determining that the block is included on the exclusion list, the processing logic performs the dynamic SLC program operation using a 1P1V scheme with an in-field read feature on only a subset of the pages of the block (e.g., the pages corresponding to a single sub-block). For example, the 1P1V scheme with the in-field read feature can be performed on the pages corresponding to a first sub-block of the block. The 1P1V scheme with the in-field read feature need not be performed on each sub-block of a block because the sub-blocks of a block can share wordlines. Therefore, verifying that a single sub-block has little or no wordline leakage can indicate that the remaining sub-blocks in the block also have little or no wordline leakage. Alternatively, the processing logic may perform the 1P1V scheme with a standard verify operation on a single sub-block of the block and a 1P0V scheme on the remaining sub-blocks of the block.

In some embodiments, the blocks on the exclusion list are not programmed using the 1P0V scheme because the potential risk a PSF is too high to omit a verify operation. The in-field read operation is specifically to be used after a program operation without a standard program verify phase, and the purpose of the in-field read operation is not to retrieve (read) data, but to identify blocks with defects (e.g., wordline leakage) so that the CFByte count can be incremented and they can be placed on the exclusion list when applicable. The in-field read operation is more sensitive, compared to a standard verify operation, in defect detection because the selected wordline in the in-field read operation is disconnected from the voltage supply and left floating for a time period (“voltage floating phase”), which can result in an amplified charge difference for detecting defects such as leakages. Also, because the outcome of the in-field read operation is defect detection, not data retrieving, the in-field read operation can be performed in parallel to multiple sub-blocks (“ganged”). By using a sensitive verify operation, such as an in-field read operation, the processing device can detect a wordline leakage of less than one nano amp.

At operation 306, in response to determining that the block is not included in the exclusion list, the processing logic determines whether the current PEC count of the block (e.g., a media endurance metric value of the block) meets a PEC count criterion. For example, the PEC count criterion can be satisfied when the PEC count value of a block is equal to one or more PEC count criterion values. These PEC count criterion values can be either periodic or random. For example, the PEC count of a block may satisfy a PEC count criterion at 10,000 PECs, 20,000 PECs, 30,000 PECs, etc. The PEC count criterion can serve as a checkpoint during the life of a block, allowing the processing device to periodically (or randomly) assess the block for any developing defects (e.g., such as wordline leakage) by using an in-field read operation.

In some embodiments, a PEC count criterion may be a logical condition (e.g., a PEC count value must be equal to a certain number of PECs (e.g., a PEC threshold value) for the PEC count criterion to be satisfied. In some embodiments, for example, checkpoints associated with the PEC count criterion may be associated with certain numbers of PECs. For example, if a PEC count value (e.g., PEC count) of a block is equal to at least one of a plurality of criterion values (e.g., PEC count values) of the PEC count criterion the block satisfies the threshold criterion. If a PEC count value (e.g., PEC count) of the block does not equal at least one of the plurality of criterion values of the PEC count criterion the block does not satisfy the PEC count criterion.

At operation 307, in response to determining that the PEC count of the block does not meet the PEC count criterion (e.g., the PEC count of the block does not equal at least one of the PEC count values that satisfy the PEC count criterion), the processing logic executes the program operation using a 1P0V scheme on all sub-blocks of the block. In some embodiments, the 1P0V scheme is a dynamic SLC program operation without any subsequent page verifications in order to reduce program operation time, improve sequential writing performance, and reduce energy consumption for the blocks that are not on the detention list and do not satisfy the PEC count criterion.

At operation 308, in response to determining that the PEC count of the block does meet the PEC count criterion (e.g., the PEC count of the block is equal to at least one of the PEC count values that satisfy the PEC count criterion), the processing logic executes the program operation on the block using a 1P1V scheme that includes an in-field read operation. This program operation on the block using the 1P1V scheme that includes in-field read operation serves as a checkpoint for processing logic to determine if the block should be added to the exclusion list or not. In some embodiments, the page program and the in-field read operation are performed on only a subset of the pages of the block. Since the sub-blocks within a block share wordlines, verifying that a single sub-block has little or no wordline leakage can indicate that the remaining sub-blocks in the block also have little or no wordline leakage.

At operation 310, the processing logic determines whether a media health metric value (e.g., a CFByte count, a wordline leakage current value, etc.) of the block satisfies a health threshold criterion. In some embodiments, the health threshold criterion is satisfied when a CFByte count of a block is greater than or equal to a CFByte threshold value. In some embodiments, leakage current (e.g., wordline leakage) in a memory device can cause unintended changes in stored data, leading to errors (e.g., PSFs). These errors can be detected by error correction mechanisms of the memory device. Specifically, the error-correcting code (ECC) identifies and corrects errors resulting from leakage currents. The CFByte count is utilized to track the frequency of these detected errors. For example, a high CFByte value indicates frequent errors due to issues like wordline leakage. Each time an error is identified and corrected (e.g., using an in-field read operation), the CFByte count is incremented, providing a metric (e.g., a media health metric) for monitoring the health and reliability of a block. When the CFByte count exceeds a predefined threshold, it may trigger actions such as marking the block as bad (e.g., exclusion list), relocating data, etc. By using an in-field read operation to detect very low leakage currents the CFByte count can be incremented even when very low leakage currents are present.

At operation 311, in response to determining that the media health metric value of the block does not satisfy the health threshold criterion the processing logic the block is not added to the exclusion list. This is because the media health metric of the block indicates that the risk of PSFs in the block is low and the block can be programmed using the 1P0V scheme (e.g., if the PEC count of the block does not satisfy the PEC count criterion).

In some embodiments, the processing logic sets, in response to determining that the media health metric of the block satisfies the health threshold criterion, an exclusion flag for the block of the memory device. The exclusion flag can then be used to determine whether to add a block to the exclusion list.

At operation 312, in response to determining that the media health metric value of the block satisfies the health threshold criterion the processing logic adds the block to the exclusion list.

In some embodiments, the present disclosure can be utilized for standard blocks as well as blocks by deck (BBD) or half-good block (HGB) usage. The present disclosure can also be extended to other nonvolatile memory (NVM) technologies, such as ReRAM and PCM, etc.

FIG. 4 illustrates example adaptive program verify scheme with sensitive verify, in accordance with one or more embodiments of the present disclosure.

In some embodiments, a horizontal axis 401 represents a PEC cycle count of a block. Segments 410 show portions of the lifetime of a block where dynamic SLC program operations are executed using a 1P0V scheme on all sub-blocks of the block. This is because the block has not yet been added to the exclusion list.

In some embodiments, segments 420 show instances where a dynamic SLC program operation is executed using a 1P1V scheme with an in-field read feature on limited pages of the block. This is because a PEC count of the block satisfied a PEC count threshold criterion and processing logic runs the 1P1V scheme with an in-field read feature on limited pages of the block to determine if the block has developed defects since the last “health check” of the block (e.g., using the in-field read feature).

In some embodiments, the 1P1V scheme with an in-field read feature on limited pages of the block can be performed on the same pages of each sub-block or varying blocks (e.g., random or rotating). In some embodiments, the in-field read feature is compatible with source to drain (S2D) or drain to source (D2S) program orders.

In some embodiments, if it is determined that that the block has developed a defect (e.g., by comparing a CFByte count of the block to a CFByte threshold count) the block is added to an exclusion list. Segment shows a portion of the lifetime of the block (e.g., the rest of the lifetime of the block) where all dynamic SLC program operations are performed on the block using a 1P1V scheme with an in-field read feature on limited pages of the block. In some embodiments, using a 1P1V scheme with an in-field read feature on limited pages of the block for every remaining dynamic SLC program in the lifetime of the block ensures that the block does not undergo any PSFs without being detected. Healthy block can benefit from using 1P0V scheme on all sub-blocks of the healthy blocks improving program time, improving sequential write performance, and reducing current consumption.

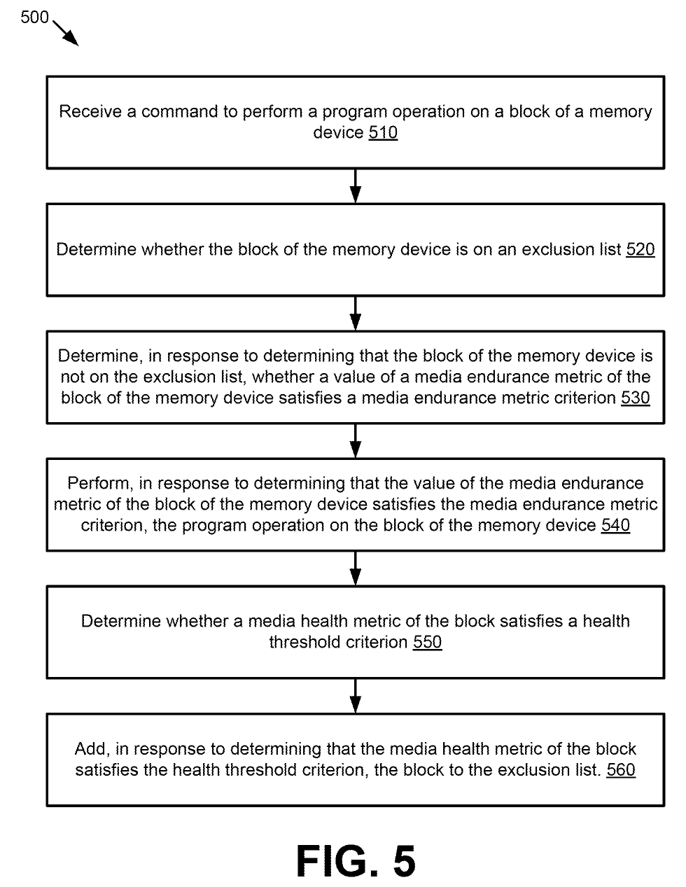

FIG. 5 is a flow diagram of an example method of implementing an in-field read operation on one or more sub-blocks to detect defects in a memory device in accordance with some embodiments of the present disclosure. The method 500 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 500 is performed by adaptive program verify scheme component 113 of FIGS. 1A and 1B. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 510, the processing logic may receive a command to perform a program operation on a block of a memory device. In some embodiments, the program operation can be a dynamic SLC program operation (e.g., using a dynamic trim setting).

In some embodiments, the block of the memory device is at least one of a block or a logical block including at least two partially good physical blocks.

At operation 520, the processing logic may determine whether the block of the memory device is on an exclusion list. In some embodiments, the processing logic performs, in response to determining that the block of the memory device is on the exclusion list, the program operation on the block of the memory device. The program operation can be a single program operation and a sensitive verify operation (e.g., 1P0V with a sensitive verify operation), wherein the single program operation and the sensitive verify operation are performed on a subset of pages of a plurality of pages of the block.

The 1P0V scheme may include one program pulse associated with a program voltage applied to a selected wordline during one time period that corresponds to the program pulse phase, and no program verify phase exists. Because there is no program verify during the program operation, no PSF will be detected. However, by using an in-field read operation (e.g., the sensitive verify operation) the processing logic can detect PSFs.

In some embodiments, the processing logic may perform, in response to determining that the block of the memory device is on the exclusion list, the program operation on the block of the memory device. The program operation can include a single program operation and a sensitive verify operation. The single program operation and the sensitive verify operation are performed on a subset of pages of a set of pages of the block.

Alternatively, the program operation can include a single program operation and a standard verify operation. The single program operation and the standard verify operation are performed on a first subset of sub-blocks of a set of sub-blocks of the block. The program operation can further include a single program operation with no subsequent verify operation. The single program operation with no subsequent verify operation are performed on a second subset of sub-blocks of the set of sub-blocks of the block. In some embodiments, the second subset of sub-blocks of the set of sub-blocks includes the remaining sub-blocks of the block. In other words, the program operation and the standard verify operation are performed on one sub-block of a corresponding subset of wordlines of a set of wordlines in the block.

At operation 530, the processing logic may determine, in response to determining that the block of the memory device is not on the exclusion list, whether a value of a media endurance metric of the block of the memory device satisfies a media endurance metric criterion.

In some embodiments, a media endurance metric criterion may be a PEC count value. A media endurance metric criterion may be a logical condition (e.g., a PEC count value must be equal to a certain number of PECs (e.g., a PEC threshold value) for the media endurance metric criterion to be satisfied. In some embodiments, for example, checkpoints associated with the media endurance metric criterion may be associate with certain numbers of PECs. For example, if a media endurance metric value (e.g., PEC count) of the block is equal to at least one of a plurality of criterion values (e.g., PEC count values) of the media endurance metric criterion of the block satisfies the threshold criterion. If a media endurance metric value (e.g., PEC count) of the block does not equal at least one of the plurality of criterion values of the media endurance metric criterion the block does not satisfy the media endurance metric criterion.

In some embodiments, the media endurance metric criterion may be based on a threshold value (e.g., a fixed PEC value, media endurance metric value, and/or the like). For example, a threshold value may be equal to a fixed number of PECs or another media endurance metric (e.g., a threshold value may be determined based on statistical data collected in post-production testing, such that the determined threshold value would optimize chosen performance or endurance metric(s)). In these and other embodiments, a media endurance metric criterion is satisfied if the media endurance metric value is equal to at least one of a plurality of criterion values of the media endurance metric criterion. In these and other embodiments, a media endurance metric criterion is not satisfied when the media endurance metric value is not equal to at least one of the plurality of criterion values of the media endurance metric criterion.

In some embodiments, a threshold criterion may be pre-defined. The media health metric can refer to a quantity that is measured or inferred from the state of data stored on the memory device. The media health metric may indicate whether cells of a block can reliably store charges due to intrinsic cell degradation resulting from repeated stresses (e.g., repeated memory access operations). The media health metric may be used to characterize voltage distributions, and reflect (i.e., is equal to or derived by a known transformation from) the state of slow charge loss, the degree of latent read disturb, the temporal voltage shift, and/or other measurable functions of the data state.

In one example, the media health metric may be represented by a program erase cycle (PEC) count and/or a temperature measurement. In some implementations, the processing logic may compare the PEC count associated with a specific block to a threshold PEC count value and determine that the media health metric satisfies the threshold criterion when the PEC count exceeds or reaches the threshold PEC count value. In some implementations, the processing logic may compare a temperature of the specific block to a threshold temperature range (e.g., including a minimum temperature level (e.g., 40°C) and a maximum temperature level (e.g., 60°C)) and determine that the media health metric satisfies the threshold criterion when the temperature exceeds the threshold temperature range.

In another example, the media health metric may be represented by the raw bit error rate (RBER), which is the number of bit error experienced by a given data block per unit of time. The media health metric may reflect the failed byte count (CFByte) and/or the failed bit count (CFBit) for a given set of memory cells. CFByte reflects the number of bytes in the sensed data that have at least one non-conducting bitline. In some embodiments, CFByte can reflect the number of bytes in the sensed data where the last bitline of the byte is a non-conducting bitline. CFBit reflects the number of non-conducting bitlines in the sensed data. In some implementations, the processing logic may determine that the media health metric associated with a specific block satisfies a threshold criterion when CFByte, or CFBit is more than or equal to a threshold value. In some embodiments, if the pre-defined CFB threshold value is low (e.g., tighter criteria), placing a block on the exclusion list (e.g., detention list) can indicate potential DPM risk instead of actual occurrence of PSF or DPM.

At operation 540, the processing logic may perform, in response to determining that the value of the media endurance metric of the block of the memory device satisfies the media endurance metric criterion, the program operation on the block of the memory device. In some embodiments, the program operation can be a single program operation and a sensitive verify operation. In some embodiments, the sensitive verify single can detect a wordline to wordline leakage of less than or equal to 1 nano amp. The single program operation and the sensitive verify operation can be performed on a subset of pages of a plurality of pages of the block.

In some embodiments, the sensitive verify operation can be an in-field read operation. The in-field read operation enables proactive recognition of memory defects, such that program status failures (PSFs) are identified during the program stage and a CFBtye count of the corresponding block can be incremented. The in-field read operation is used in the case that no program verify is performed during the program operation, and as such, the in-field read operation provides a mechanism to promote the data integrity while keeping the merits provided by program operation without program verify, such as reduced time of program operation, better sequential writing performance, and reduced energy consumption of program operation. An in-field read operation can identify blocks that have failed to be programmed (e.g., PSF).

In some embodiments, the in-field read operation includes a voltage floating phase, and a voltage supply to a wordline is withdrawn during the voltage floating phase. The in-field read operation is similar to a read operation except that the in-field read operation includes a phase floating the voltage. Performing the in-field read operation may involving applying voltages to wordlines such that a selected wordline (i.e., the target wordline for defect detection) is pre-charged during a charging time to a pass voltage level (Vpass) and then is biased to the read threshold voltage (Vwlrv), and then is disconnected from the voltage supply and left floating, while the unselected wordline (e.g., the adjacent wordlines of the target wordline) is set to a pass voltage level (Vpass). The result of the in-field read operation may involving measuring a current and comparing the current with reference values to determine whether the sub-blocks contains defects, and based on the determination, outputting a result indicating whether a read status failure of the block is detected or not.

In some implementations, responsive to detecting a read status failure as a result of performing the in-field read operation, the IFR component may increment a CFByte of the corresponding block. Because the data that is supposed to be programmed in the block may be affected by the defect detected in the block, the processing logic may retrieve the data, which may be still stored in a memory cache (e.g., hardware memory buffer), and switch to another block to program the data. Advantageously, the in-field read operation enables the re-programming of data after programming a block that becomes a hard failure, thereby avoiding data loss and reducing the corresponding reliability risk. In some embodiments, instead of using the in-field read for classification between good blocks and grown bad blocks, in-field read can be used to identify blocks for an exclusion list (e.g., detention list).

At operation 550, the processing logic may determine whether a media health metric of the block satisfies a health threshold criterion.

In some embodiments, the processing logic may perform, in response to determining that the value of the media endurance metric of the block of the memory device does not satisfy the media endurance metric criterion, the program operation on the block of the memory device. The program operation can include a single program operation with no subsequent verify operation (e.g., 1P0V scheme).

At operation 560, the processing logic may add, in response to determining that the media health metric of the block satisfies the health threshold criterion, the block to the exclusion list.

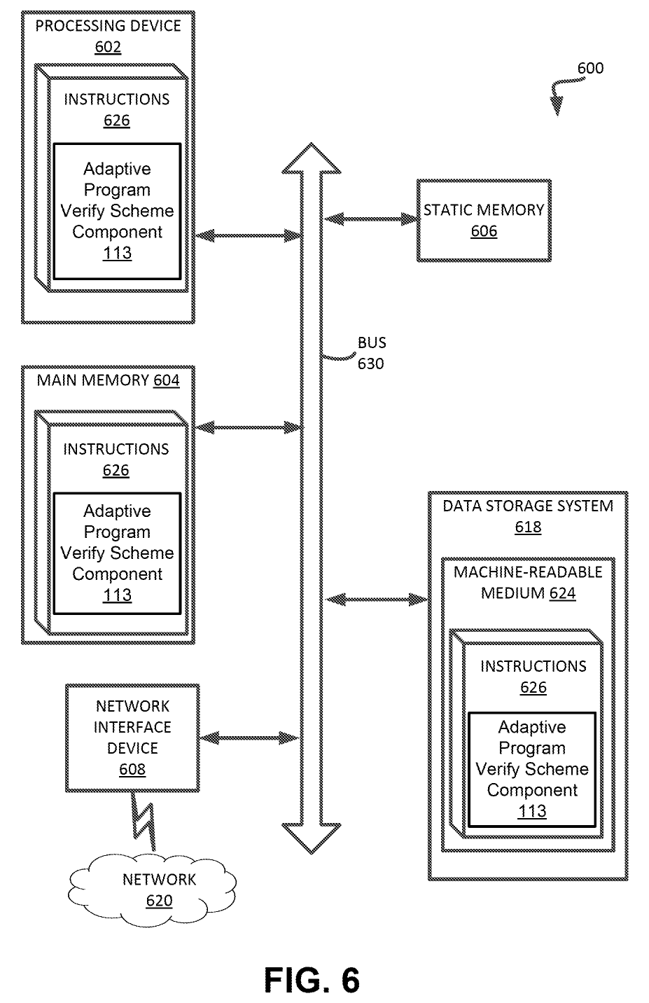

FIG. 6 illustrates an example machine of a computer system 600 within which a set of instructions, for causing the machine to perform any one or more of the methodologies discussed herein, can be executed. In some embodiments, the computer system 600 can correspond to a host system (e.g., the host system 120 of FIG. 1A) that includes, is coupled to, or utilizes a memory sub-system (e.g., the memory sub-system 110 of FIGS. 1A and 1B) or can be used to perform the operations of a controller (e.g., to execute an operating system to perform operations corresponding to the IFR component 113 of FIGS. 1A and 1B). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a data storage system 618, which communicate with each other via a bus 630.

Processing device 602 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 602 can also be one or more special-purpose processing devices such as an application specific integrated circuit (ASIC), a field programmable gate array (FPGA), a digital signal processor (DSP), network processor, or the like. The processing device 602 is configured to execute instructions 626 for performing the operations and steps discussed herein. The computer system 600 can further include a network interface device 608 to communicate over the network 620.

The data storage system 618 can include a machine-readable storage medium 624 (also known as a computer-readable medium) on which is stored one or more sets of instructions 626 or software embodying any one or more of the methodologies or functions described herein. The instructions 626 can also reside, completely or at least partially, within the main memory 604 and/or within the processing device 602 during execution thereof by the computer system 600, the main memory 604 and the processing device 602 also constituting machine-readable storage media. The machine-readable storage medium 624, data storage system 618, and/or main memory 604 can correspond to the memory sub-system 110 of FIGS. 1A and 1B.

In one embodiment, the instructions 626 include instructions to implement functionality corresponding to the adaptive program verify scheme component 113 of FIGS. 1A and 1B). While the machine-readable storage medium 624 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A system, comprising: a memory device; and processing device operatively coupled to the memory device, the processing device to perform operations, comprising: receiving a command to perform a program operation on a block of the memory device determining whether the block of the memory device is on an exclusion list; determining, in response to determining that the block of the memory device is not on the exclusion list, whether a value of a media endurance metric of the block of the memory device satisfies a media endurance metric criterion ;performing, in response to determining that the value of the media endurance metric of the block of the memory device satisfies the media endurance metric criterion, the program operation on the block of the memory device; determining whether a media health metric of the block satisfies a health threshold criterion; and adding, in response to determining that the media health metric of the block satisfies the health threshold criterion, the block to the exclusion list.

2. The system of claim 1, wherein the program operation comprises a single program operation and a sensitive verify operation, and wherein the single program operation and the sensitive verify operation are performed on a subset of pages of a plurality of pages of the block.

3. The system of claim 2, wherein the sensitive verify operation comprises an in-field read operation.

4. The system of claim 2, wherein the sensitive verify operation can detect a wordline to wordline leakage of less than or equal to 1 nano amp.

5. The system of claim 1, wherein the operations further comprise: performing, in response to determining that the block of the memory device is on the exclusion list, the program operation on the block of the memory device, wherein the program operation comprises: a single program operation and a sensitive verify operation, wherein the program operation and the sensitive verify operation are performed on a subset of pages of a plurality of pages of the block.

6. The system of claim 1, wherein the operations further comprise: performing, in response to determining that the block of the memory device is on the exclusion list, the program operation on the block of the memory device, wherein the program operation comprises: a single program operation and a standard verify operation, wherein the single program operation and the standard verify operation are performed on a first subset of sub-blocks of a plurality of sub-blocks of the block; and a single program operation with no subsequent verify operation, wherein the single program operation with no subsequent verify operation is performed on a second subset of sub-blocks of the plurality of sub-blocks of the block.

7. The system of claim 1, wherein the operations further comprise: performing, in response to determining that the value of the media endurance metric of the block of the memory device does not satisfy the media endurance metric criterion, the program operation on the block of the memory device, wherein the program operation comprises a single program operation with no subsequent verify operation.

8. The system of claim 1, wherein the program operation comprises a dynamic SLC program operation.

9. The system of claim 1, wherein the block of the memory device is at least one of a block or a logical block comprising at least two partially good physical blocks.

10. A method, comprising: receiving, by a processing device, a command to perform a program operation on a block of a memory device; determining whether the block of the memory device is on an exclusion list; determining, in response to determining that the block of the memory device is not on the exclusion list, whether a value of a media endurance metric of the block of the memory device satisfies a media endurance metric criterion; performing, in response to determining that the value of the media endurance metric of the block of the memory device satisfies the media endurance metric criterion, the program operation on the block of the memory device; determining whether a media health metric of the block satisfies a health threshold criterion; and adding, in response to determining that the media health metric of the block satisfies the health threshold criterion, the block to the exclusion list.

11. The method of claim 10, wherein the program operation comprises a single program operation and a sensitive verify operation, and wherein the single program operation and the sensitive verify operation are performed on a subset of pages of a plurality of pages of the block.

12. The method of claim 11, wherein the sensitive verify operation comprises an in-field read operation.

13. The method of claim 11, wherein the sensitive verify operation can detect a wordline to wordline leakage of less than or equal to 1 nano amp.

14. The method of claim 10, further comprising: performing, in response to determining that the block of the memory device is on the exclusion list, the program operation on the block of the memory device, wherein the program operation comprises: a single program operation and a sensitive verify operation, wherein the single program operation and the sensitive verify operation are performed on a subset of pages of a plurality of pages of the block.

15. The method of claim 10, further comprising: performing, in response to determining that the block of the memory device is on the exclusion list, the program operation on the block of the memory device, wherein the program operation comprises: a single program operation and a standard verify operation, wherein the single program operation and the standard verify operation are performed on a first subset of sub-blocks of a plurality of sub-blocks of the block; and a single program operation with no subsequent verify operation, wherein the single program operation with no subsequent verify operation are performed on a second subset of sub-blocks of the plurality of sub-blocks of the block.

16. The method of claim 10, further comprising: performing, in response to determining that the value of the media endurance metric of the block of the memory device does not satisfy the media endurance metric criterion, the program operation on the block of the memory device, wherein the program operation comprises a single program operation with no subsequent verify operation.

17. The method of claim 10, wherein the program operation comprises a dynamic SLC program operation.

18. A non-transitory computer-readable storage medium storing instructions, which when executed by a processing device, cause the processing device to perform operations, comprising: receiving a command to perform a program operation on a block of a memory device determining whether the block of the memory device is on an exclusion list; determining, in response to determining that the block of the memory device is not on the exclusion list, whether a value of a media endurance metric of the block of the memory device satisfies a media endurance metric criterion; performing, in response to determining that the value of the media endurance metric of the block of the memory device satisfies the media endurance metric criterion, the program operation on the block of the memory device;
determining whether a media health metric of the block satisfies a health threshold criterion; and
adding, in response to determining that the media health metric of the block satisfies the health threshold criterion, the block to the exclusion list.

19. The non-transitory computer-readable storage medium of claim 18, wherein the program operation comprises a single program operation and a sensitive verify operation, wherein the sensitive verify operation can detect a wordline to wordline leakage of less than or equal to 1 nano amp, and wherein the single program operation and the sensitive verify operation are performed on a subset of pages of a plurality of pages of the block.

20. The non-transitory computer-readable storage medium of claim 18, wherein the operations further comprise: performing, in response to determining that the value of the media endurance metric of the block of the memory device does not satisfy the media endurance metric criterion, the program operation on the block of the memory device, wherein the program operation comprises a single program operation with no subsequent verify operation.
